(19) United States
(12) Patent Application Publication
(10) Pub. No.: US 2016/0351750 A1
(43) Pub. Date: Dec. 1, 2016

(54) Fabrication Method of Nitride Light Emitting Diodes

(71) Applicant: XIAMEN SANAN OPTOELECTRONICS TECHNOLOGY CO., LTD., Xiamen (CN)

(72) Inventors: Musen DONG, Xiamen (CN); Liying SHEN, Xiamen (CN); Duxiang WANG, Xiamen (CN); Liangjun WANG, Xiamen (CN); Xiaofeng LIU, Xiamen (CN)

(73) Assignee: XIAMEN SANAN OPTOELECTRONICS TECHNOLOGY CO., LTD., Xiamen (CN)

(21) Appl. No.: 15/235,092

(22) Filed: Aug. 11, 2016

Related U.S. Application Data
(63) Continuation of application No. PCT/CN2014/094874, filed on Dec. 25, 2014.

(30) Foreign Application Priority Data
May 21, 2014 (CN) 201410215285.0

(51) Int. Cl. H01L 33/32; H01L 33/06; H01L 33/62; H01L 33/12; H01L 33/00

(52) U.S. Cl. CPC H01L 33/32; H01L 33/12; H01L 33/0075; H01L 33/0079; H01L 33/62; H01L 33/06; H01L 2933/0066

(57) ABSTRACT

A fabrication method of nitride LEDs, which reduces electron leakage and efficiency droop and improves hole concentration and light emitting efficiency, the method including: (1) providing an intermediate substrate; (2) growing a P-type semiconductor layer and a first bonding layer on the intermediate substrate in sequence; (3) providing a permanent substrate; (4) growing an N-type semiconductor layer, a light emitting layer and a second bonding layer on the permanent substrate; (5) bonding the intermediate substrate with the P-type semiconductor layer and the permanent substrate with the N-type semiconductor layer and the light emitting layer through the first bonding layer and the second bonding layer.

### CROSS-REFERENCE TO RELATED APPLICATIONS

The present application is a continuation of, and claims priority to, PCT/CN2014/094874 filed on Dec. 25, 2014, which claims priority to Chinese Patent Application No. 201410215285.0 filed on May 21, 2014. The disclosures of these applications are hereby incorporated by reference in their entirety.

### BACKGROUND

In recent years, light emitting diodes (LEDs), with a focus on luminance improvement, are desired to be applied in the lighting field for energy saving and carbon reduction. In general, a conventional InGaN LED is a structure laminated with a nitride buffer layer on the sapphire substrate, a Si-doped GaN n-type contact layer, a light emitting layer with an InGaN multi-quantum-well (MQW) structure, a Mg-doped AlGaN electron blocking layer, a Mg-doped p-type nitride contact layer in sequence, which is featured with high luminance.

In general, InGaN LED structures, the growth temperature of the MQW light emitting layer is 750° C.-850° C., and that of the P-type semiconductor layer is higher at 900° C.-1,000° C. in general. However, as the temperature of the P-type semiconductor layer gets higher, there is huger damage to the light emitting layer, thus reducing the composite efficiency and influencing the light emitting efficiency. However, temperature decrease of the P-type layer will reduce crystal quality of the P-type semiconductor layer. By far, electronic leakage and low hole concentration are the major causes for efficiency droop, which restrict efficiency improvement and wide application of the LEDs. Therefore, it is necessary to invent a brand-new fabrication method to solve the above problems.

### SUMMARY

To solve the above problems, the present disclosure provides a fabrication method of nitride LEDs, which enables high-temperature growth of the P-type semiconductor layer and avoids damage to the MQW layer, comprising: (1) providing an intermediate substrate; (2) growing a P-type semiconductor layer and a first bonding layer on the intermediate substrate; (3) providing a permanent substrate; (4) growing an N-type semiconductor layer, a light emitting layer and a second bonding layer on the permanent substrate; (5) bonding the intermediate substrate with the P-type semiconductor layer and the permanent substrate with the N-type semiconductor layer and the light emitting layer through the first bonding layer and the second bonding layer.

The first bonding layer and the second bonding layer can be bonded with chip bonding or die bonding, and chip bonding is preferable. Direct bonding or medium bonding is acceptable, and direct bonding is preferable, which is further divided into thermal bonding and low temperature vacuum bonding.

In some embodiments, after bonding of the first bonding layer and the second bonding layer, the intermediate substrate is removed.

In some embodiments, after removal of the intermediate substrate, some parts of the N-type semiconductor layer are exposed through etching; and a P electrode and an N electrode are fabricated respectively on the P-type semiconductor layer and the exposed N-type semiconductor layer.

In some embodiments, the first bonding layer/the second bonding layer is an Al_{1-x-y}Ga_{xInyN} layer, where, 0≦x<y, 0≦y<1.

In some embodiments, the intermediate substrate is made of single crystal alumina (sapphire), SiC (6H—SiC or 4H—SiC), Si, GaAs, GaN or any of their combinations.

In some embodiments, the permanent substrate is made of single crystal alumina (sapphire), SiC (6H—SiC or 4H—SiC), Si, GaAs, GaN or any of their combinations.

In some embodiments, the P-type semiconductor layer can comprise, in sequence, a P-type contact layer, a P-type layer and an electron blocking layer.

In some embodiments, a transparent conducting layer can be made between the intermediate substrate and the P-type semiconductor layer.

In some embodiments, a buffer layer can be made between the permanent substrate and the N-type semiconductor layer.

In some embodiments, the buffer layer can be a low-temperature buffer layer or a high-temperature buffer layer or their combination.

In another aspect, a nitride LED is provided, fabricated with the above method.

In another aspect, a light-emitting system is provided including a plurality of the nitride LEDs fabricated with the above method. The system can be used in, for example, lighting, displays, etc.

Compared with existing fabrication methods of nitride LEDs, the fabrication method through bonding according to some embodiments the present disclosure can have one or more of the following advantages: (1) the light emitting efficiency is improved for it avoids damage to the light emitting layer due to direct growth of the P-type semiconductor layer; (2) the growth temperature of the P-type semiconductor layer is increased, and it is good for doping and improving hole concentration (the growth conditions of the P-type semiconductor layer are optimized without being restricted by the light emitting layer); (3) in general, in InGaN LED structures, the electron blocking layer interface has positive polarization plane charges that induce electrons, which reduce potential barrier of the electron blocking layer and cause electron leakage from the light emitting layer. According to some embodiments of the present disclosure, however, the polarization charges of the electron blocking layer are reversed into negative polarization charges and the electrons are restricted in the light emitting layer, thus reducing electron leakage, increasing composite efficiency and improving light emitting efficiency.

Advantageously, various embodiments of the present disclosure can reduce electron leakage and efficiency droop and improve hole concentration and light emitting efficiency, and is applicable for fabrication of the semiconductor devices.

### BRIEF DESCRIPTION OF THE DRAWINGS

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

FIG. 1 is a schematic diagram of a step in a fabrication method of nitride LEDs according to some embodiments of the present disclosure; and

FIG. 2 is a schematic diagram of another step in a fabrication method of nitride LEDs according to some embodiments of the present disclosure.

In the drawings:

100: intermediate substrate; 101: transparent conducting layer; 102: P-type semiconductor layer; 102a: P-type contact layer; 102b: P-type layer; 102c: electron blocking layer; 103a: first GaN layer; 103b: second GaN layer; 104: permanent substrate; 105a: low-temperature buffer layer; 105b: high-temperature buffer layer; 106: N-type semiconductor layer; 107: light emitting layer; 108: N electrode; 109: P electrode.

### DETAILED DESCRIPTION

The embodiments of the present disclosure will be described in detail with reference to the accompanying drawings and embodiments.

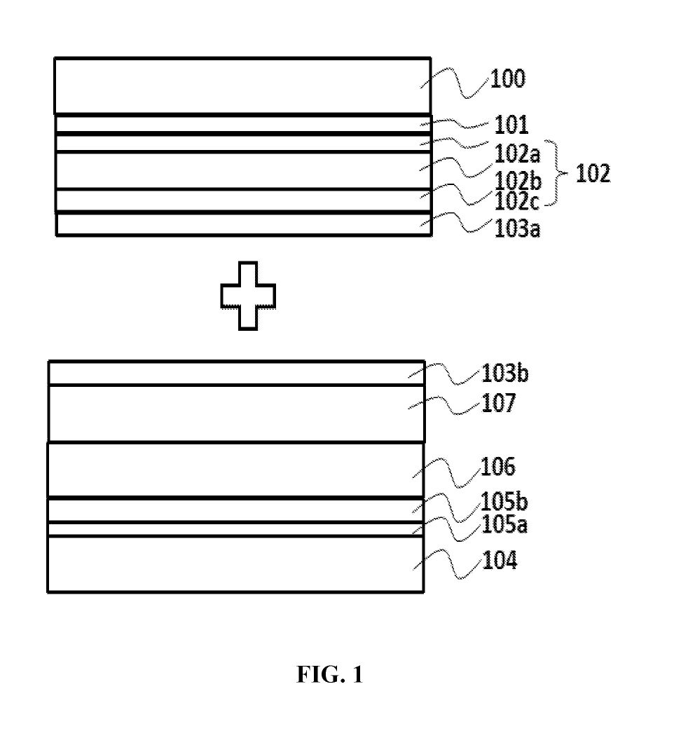

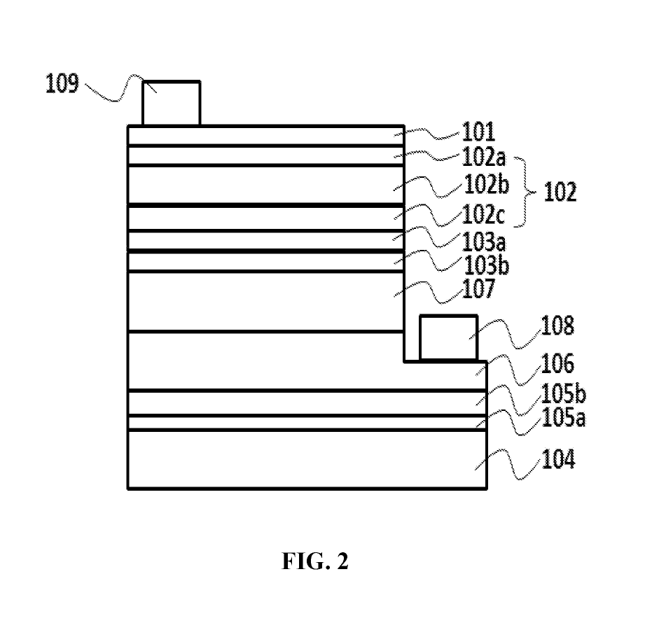

As shown in FIGS. 1-2, a fabrication method of nitride LEDs is provided following the steps below:

(1) Providing an intermediate substrate 100 made of single crystal alumina (sapphire), SiC (6H—SiC or 4H—SiC), Si, GaAs, GaN or any of their combinations, and a Si substrate is preferred in this embodiment;

(2) Forming a transparent conducting layer 101 made of ITO, IZO, ZnO, GZO, including SiO-based ITO, on the intermediate substrate 100, and ITO is preferred in this embodiment;

(3) Growing a P-type semiconductor layer 102 and a first GaN layer 103a on the transparent conducting layer 101, wherein, the P-type semiconductor layer comprises a P-type contact layer, a P-type layer and an electron blocking layer; and the first GaN layer 103a is 1-100 nm thick, preferably, 10 nm;

(4) Providing a permanent substrate 104 made of single crystal alumina (sapphire), SiC (6H—SiC or 4H—SiC), Si, GaAs, GaN or any of their combinations, including single crystalline oxides whose lattice constant is approximate to that of the nitride semiconductors, and a Sapphire substrate is preferred in this embodiment;

(5) Growing a low-temperature buffer layer 105a, a high-temperature buffer layer 105b, an N-type semiconductor layer 106, a light emitting layer 107 and a second GaN layer 103b in sequence on the permanent substrate 104, wherein, the buffer layer is made of Al_{1-x-y}GaₓIn_{y}N, where 0≦x<y, 0≦y<1; and the second GaN layer 103b is 1-100 nm thick, preferably, 10 nm;

(6) Bonding the intermediate substrate 100 with the P-type semiconductor layer 102 and the permanent substrate 104 with the N-type semiconductor layer 106 and the light emitting layer 107 through the first GaN layer 103a and the second GaN layer 103b via low-temperature vacuum bonding; a flat, clean and more active wafer surface is obtained after cleaning and activation by plasmas under vacuum environment and the annealing temperature required for bonding is further reduced, thus achieving better bonding effect, reducing damages to the bonding layer, the light emitting layer (MQW layer) and the P-type semiconductor layer. Specifically, bonding parameters are listed below: the bonding temperature is lower than the growth temperatures of the light emitting layer and the bonding layer, in general 100-600° C., and preferably 300° C.; the bonding vacuum degree is below 10⁻³ Pa; the bonding pressure is 10-1,000 N/cm², and the bonding time is 1-100 min;

(7) Removing the intermediate substrate 100;

(8) Exposing some parts of the N-type semiconductor layer through etching; and fabricating a P electrode 109 and an N electrode 108 respectively on the P-type semiconductor layer and the exposed N-type semiconductor layer to complete fabrication of the nitride LEDs.

The abovementioned fabrication method for nitride LEDs has the benefits below: the light emitting efficiency is improved for it avoids damage to the light emitting layer due to direct growth of the P-type semiconductor layer; the growth conditions of the P-type semiconductor layer are optimized without being restricted by the light emitting layer; the P-type growth temperature is increased, and it is good for doping and improving hole concentration; the polarization charges of the electron blocking layer are reversed and the electrons are restricted in the light emitting layer, thus reducing electron leakage and increasing composition. Therefore, the present disclosure can reduce electron leakage and efficiency droop and improve hole concentration and light emitting efficiency.

It should be noted that, though a GaN layer is used as the bonding material in the aforesaid embodiments, other semiconductor materials are also acceptable. For example, the first bonding layer/the second bonding layer can be Al_{1-x-y}GaₓIn_{y}N layer, where 0≦x<y, 0≦y<1; and this bonding layer material can be P-doped (e.g., Mg) or not doped.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A method of fabricating nitride LEDs, the method comprising:
(1) providing an intermediate substrate;
(2) growing a P-type semiconductor layer and a first bonding layer over the intermediate substrate;
(3) providing a permanent substrate;
(4) growing an N-type semiconductor layer, a light emitting layer, and a second bonding layer over the permanent substrate; and
(5) bonding the intermediate substrate with the P-type semiconductor layer and the permanent substrate with the N-type semiconductor layer and the light emitting layer through the first bonding layer and the second bonding layer.

2. The method of claim 1, wherein the first bonding layer and the second bonding layer comprise an Al_{1-x-y}GaₓIn_{y}N layer, and wherein 0≦x<y, 0≦y<1.

3. The method of claim 1, wherein the bonding comprises at least one of a direct bonding or a medium bonding.

4. The method of claim 3, wherein the direct bonding is thermal bonding or low-temperature vacuum bonding.

5. The method of claim 1, further comprising, after bonding of the first bonding layer and the second bonding layer, removing the intermediate substrate.

6. The method of claim 5, further comprising, after removal of the intermediate substrate, exposing a portion of the N-type semiconductor layer through etching; and fabricating a P electrode and an N electrode respectively over the P-type semiconductor layer and the exposed portion of the N-type semiconductor layer.

7. The method of claim 1, wherein the intermediate substrate and the permanent substrate comprise at least one of single crystal alumina (sapphire), SiC (6H—SiC or 4H—SiC), Si, GaAs, or GaN.

8. The method of claim 1, wherein the P-type semiconductor layer comprises a P-type contact layer, a P-type layer, and an electron blocking layer.

9. The method of claim 1, further comprising: forming a transparent conducting layer between the intermediate substrate and the P-type semiconductor layer.

10. The method of claim 1, further comprising: forming a buffer layer between the permanent substrate and the N-type semiconductor layer.

11. A nitride LED, comprising:
a transparent conducting layer;
a P-type semiconductor layer;
a first GaN layer;
a second GaN layer;
a permanent substrate;
a low-temperature buffer layer;
a high-temperature buffer layer;
an N-type semiconductor layer;
a light emitting layer;
an N electrode; and
a P electrode;
wherein the LED is fabricated by:
(1) providing an intermediate substrate;
(2) growing the P-type semiconductor layer and a first bonding layer over the intermediate substrate;
(3) providing the permanent substrate;
(4) growing the N-type semiconductor layer, the light emitting layer, and a second bonding layer over the permanent substrate; and
(5) bonding the intermediate substrate with the P-type semiconductor layer and the permanent substrate with the N-type semiconductor layer and the light emitting layer through the first bonding layer and the second bonding layer.

12. The LED of claim 11, wherein the first bonding layer and the second bonding layer comprise an Al_{1-x-y}GaₓIn_{y}N layer, and wherein 0≦x<y, 0≦y<1.

13. The LED of claim 11, wherein the bonding comprises at least one of a direct bonding or a medium bonding.

14. The LED of claim 13, wherein the direct bonding is thermal bonding or low-temperature vacuum bonding.

15. The LED of claim 11, wherein after bonding of the first bonding layer and the second bonding layer, the intermediate substrate is removed.

16. The LED of claim 15, wherein after removal of the intermediate substrate, a portion of the N-type semiconductor layer is exposed through through etching; and the P electrode and the N electrode are respectively fabricated over the P-type semiconductor layer and the exposed portion of the N-type semiconductor layer.

17. The LED of claim 11, wherein the intermediate substrate and the permanent substrate comprise at least one of single crystal alumina (sapphire), SiC (6H—SiC or 4H—SiC), Si, GaAs, or GaN.

18. The LED of claim 11, wherein the P-type semiconductor layer comprises a P-type contact layer, a P-type layer, and an electron blocking layer.

19. The LED of claim 11, further comprising: a transparent conducting layer between the intermediate substrate and the P-type semiconductor layer; and a buffer layer between the permanent substrate and the N-type semiconductor layer.

20. A light-emitting system comprising a plurality of nitride LEDs, each LED comprising:
a transparent conducting layer;
a P-type semiconductor layer;
a first GaN layer;
a second GaN layer;
a permanent substrate;
a low-temperature buffer layer;
a high-temperature buffer layer;
an N-type semiconductor layer;
a light emitting layer;
an N electrode; and
a P electrode;
wherein the LED is fabricated by:
(1) providing an intermediate substrate;
(2) growing the P-type semiconductor layer and a first bonding layer over the intermediate substrate;
(3) providing the permanent substrate;
(4) growing the N-type semiconductor layer, the light emitting layer, and a second bonding layer over the permanent substrate; and
(5) bonding the intermediate substrate with the P-type semiconductor layer and the permanent substrate with the N-type semiconductor layer and the light emitting layer through the first bonding layer and the second bonding layer.
